(19) United States
(12) Patent Application Publication
(10) Pub. No.: US 2013/0114213 A1
(43) Pub. Date: May 9, 2013

(54) ELECTRONIC DEVICE

(71) Applicants: Tsai-Chih Tsai, Hsinchu (TW); Yin-Chieh Hsueh, Hsinchu (TW); Shih-Ya Lin, Hsinchu (TW)

(72) Inventors: Tsai-Chih Tsai, Hsinchu (TW); Yin-Chieh Hsueh, Hsinchu (TW); Shih-Ya Lin, Hsinchu (TW)

(73) Assignee: SILICON INTERGRATED SYSTEMS CORP., Hsinchu (TW)

(21) Appl. No.: 13/292,676

(22) Filed: Nov. 9, 2011

(51) Int. Cl. H05K 7/20

(52) U.S. Cl. 361/717; 174/252

(57) ABSTRACT

An electronic device having a base includes a circuit board, a electronic element, and a heat sink. The electronic element is mounted on the circuit board. The heat sink attaches to the electronic element. The heat sink includes an attaching wall and at least one side wall. The attaching wall attaches to the electronic element and having two opposite ends. At least one side wall connects to the ends of the attaching wall. The side wall and the attaching wall form a tube with an intake opening and an outtake opening. The intake opening faces the base and the outtake opening is opposite to the intake opening.

### BACKGROUND

1. Technical Field

The present disclosure relates to an electronic device, and more particularly to an electronic device having a heat sink.

2. Related Art

In recent years, electronic devices get thinner and thinner, and computing speed of the electronic devices become faster and faster. Accordingly, the temperature of the electronic element in the electronic device increases rapidly, when the electronic device is in use. Typically, a heat sink is needed to remove the generated heat to lower the temperature of the electronic element.

FIG. 1 is a perspective view of a conventional electronic device 11. A heat sink 112 is mounted on a circuit board 111 in the electronic device 11 to dissipate the heat of the circuit board 111 to the ambient. Typically, it is considered that fins are capable of increasing heat dissipation area, and therefore increases heat-dissipation efficiency. Therefore, the conventional heat sink 112 employs several fins 112a.

### SUMMARY

According to an embodiment of the present disclosure, an electronic device comprises a circuit board, an electronic element, and a heat sink. The electronic element is mounted on the circuit board. The heat sink attaches to the electronic element. The heat sink comprises an attaching wall and at least one side wall. The attaching wall attaches to the electronic element and having two opposite ends. At least one side wall connects to the ends of the attaching wall. The side wall and the attaching wall form a tube with an intake opening and an outtake opening. The intake opening faces the base, and the outtake opening is opposite to the intake opening.

### BRIEF DESCRIPTION OF THE DRAWINGS

The present disclosure will become more fully understood from the following detailed description when taken in connection with the accompanying drawings, which show, for purpose of illustrations only, and thus do not limit other possible embodiments derived from the spirit of the present disclosure, and wherein:

FIG. 1 is a perspective view of a conventional electronic device;

FIG. 2A is a perspective view of an electronic device according to an embodiment;

FIG. 2B is an exploded view of the circuit board, the electronic element and the heat sink in FIG. 2A;

FIG. 3 is a sectional view of the electronic device as taken along line 3-3 in FIG. 2A;

FIG. 4A is a sectional view of the electronic device as taken along line 4A-4A in FIG. 2A;

FIG. 4B is a sectional view of an electronic device according to another embodiment;

FIG. 4C is a sectional view of an electronic device according to another embodiment;

FIG. 4D is a sectional view of an electronic device according to another embodiment;

FIG. 5A is an exploded view of a combination of a circuit board, an electronic element and a heat sink according to another embodiment;

FIG. 5B is an exploded view of a combination of a circuit board, an electronic element and a heat sink according to another embodiment;

FIG. 5C is an exploded view of a combination of a circuit board, an electronic element and a heat sink according to another embodiment;

FIG. 5D is an exploded view of a combination of a circuit board, an electronic element and a heat sink according to another embodiment;

FIG. 6A is a perspective view of an electronic device according to another embodiment;

FIG. 6B is a back view of the electronic device in FIG. 6A;

FIG. 7A is a perspective view of an electronic device according to another embodiment; and

FIG. 7B is a sectional view of the electronic device, as taken along line 7B-7B in FIG. 7A.

### DETAILED DESCRIPTION

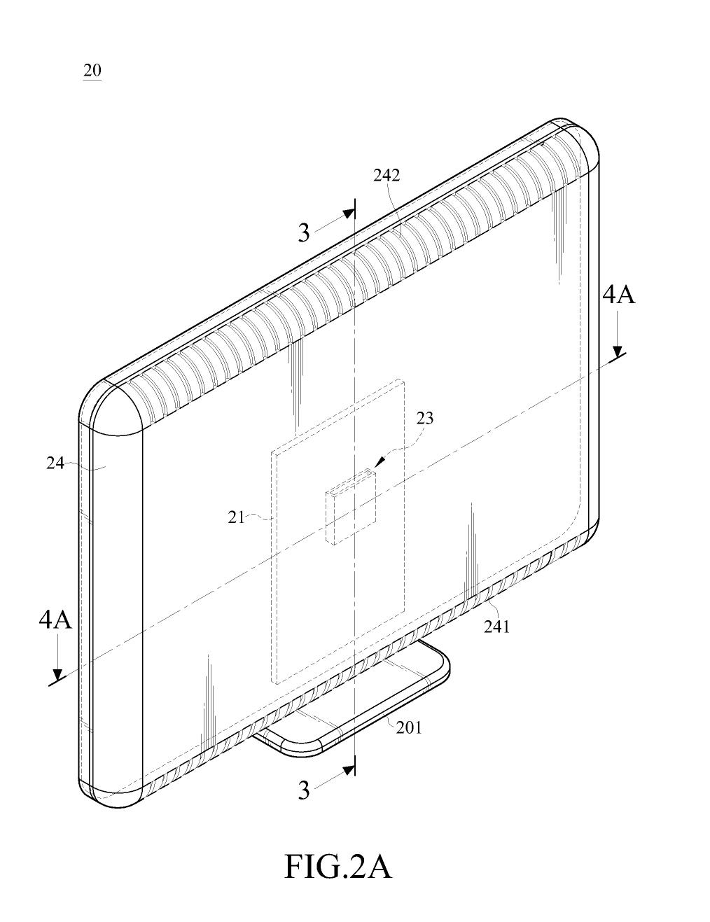

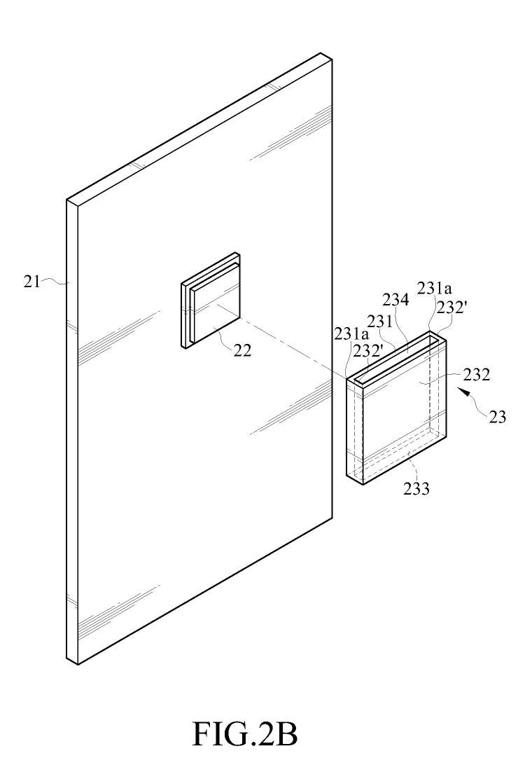

FIG. 2A is a perspective view of an electronic device 20 according to an embodiment. The electronic device 20 has a base 201. The electronic device 20 is a display or a television, for example. FIG. 2B is an exploded view of a portion of the electronic device 20 in FIG. 2A. The electronic device 20 includes a circuit board 21, an electronic element 22, and a heat sink 23. The electronic element 22 is mounted on and electrically connected to the circuit board 21. The electronic element is a chip, such as a CPU. The heat sink 23 attaches to the electronic element 22 so as to dissipate the heat generated by the electronic element 22. The heat sink 23 includes an attaching wall 231 and at least one side wall. In this embodiment, the attaching 231 wall is rectangular. However, this embodiment is not intended to limit the shape of the attaching wall 231. In some embodiments, the shape of the attaching wall 231 is circular or other shape. The attaching wall 231 attaches to the electronic element 22 and has two opposite ends 231a. In this embodiment, the heat sink 23 includes three rectangular side walls 232 and 232′. However, this embodiment is not intended to limit the number of the side walls. The side walls 232′ connect to the ends 231a of the attaching wall 231, respectively. The side walls 232 and 232′ and the attaching wall 231 form a tube with an intake opening 233 and an outtake opening 234. The intake opening 233 and the outtake opening 234 are opposite to each other. The electronic device 20 further includes a housing 24 covering the circuit board 21, the electronic element 22, and the heat sink 23. The housing 24 has an intake hole 241 and an outtake hole 242. The intake hole 241 is close to the base 201, and the outtake hole 242 is away from the base 201.

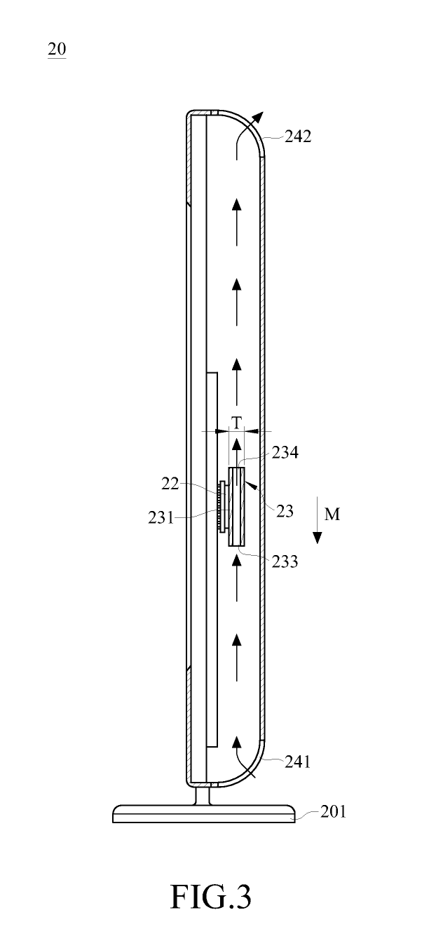

FIG. 3 is a sectional view of the electronic device 20 as taken along line 3-3 in FIG. 2A. The intake opening 233 faces the base 201 and the outtake opening 234 is opposite to the intake opening 233. The thickness T of the heat sink 23 is equal to or smaller than, for example, 10 mm. The heat sink 23 is made of, for example, aluminum or copper.

When being in use, the electronic device 20, for example, stands on a desk through the base 201. Accordingly, a part of the heat of the electronic element 22 is conducted to the air in the heat sink by the attaching wall 231. Since the density of the hot air is smaller than the density of the cold air, the hot air moves in a direction opposite to the gravity direction M when natural convection occurs. Therefore, the hot air in the heat sink 23 is removed from the outtake opening 234 due to the natural convection, and the cold air near the intake opening 233 is attracted into the heat sink 23 so that the temperature the electronic element 22 is lowered.

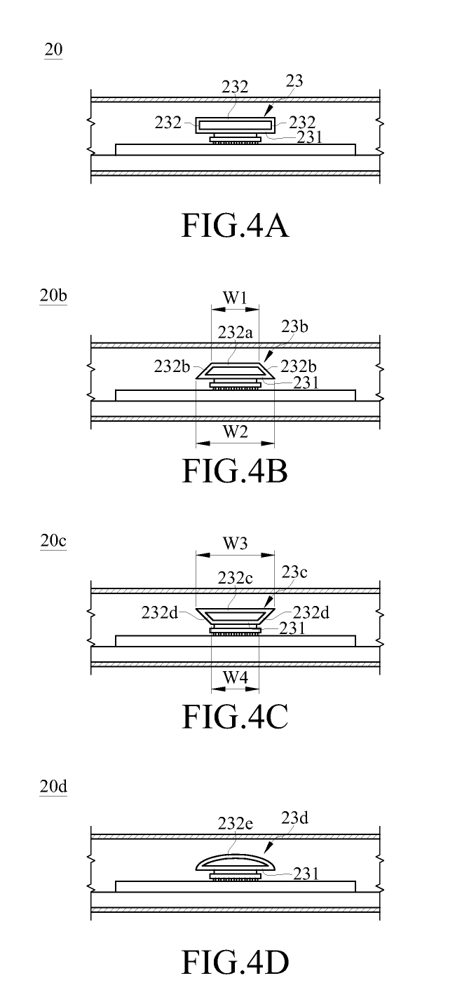

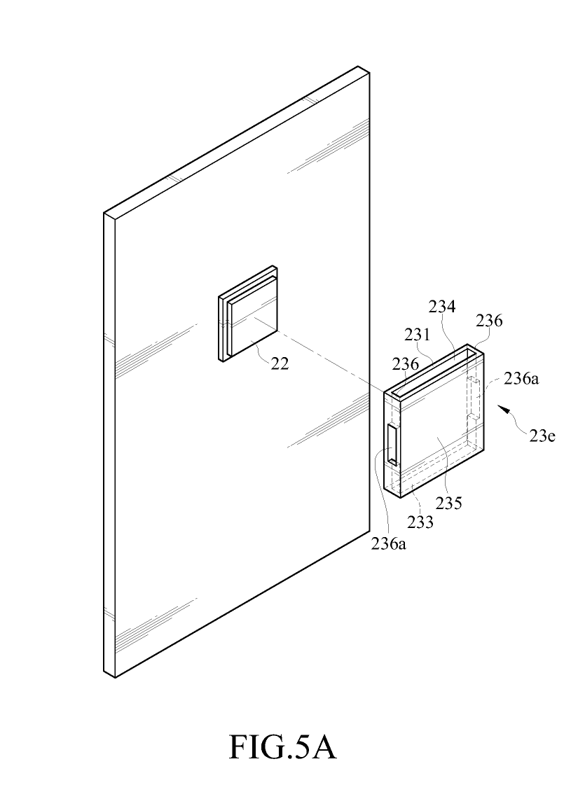

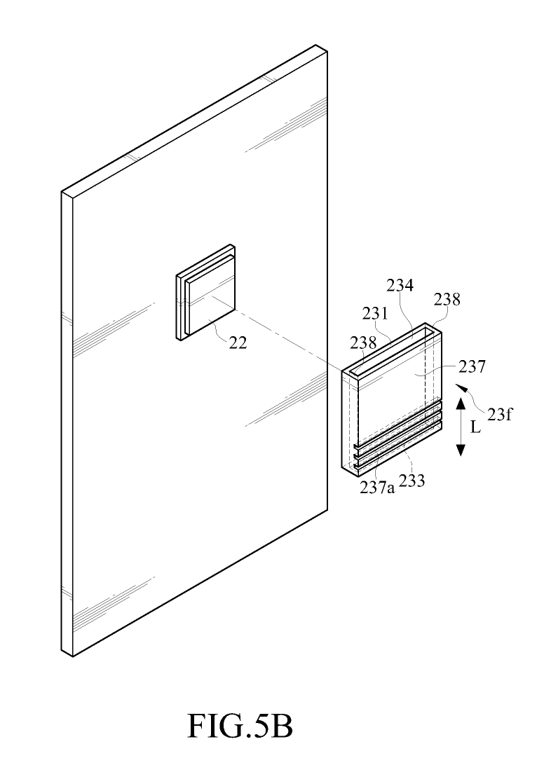

FIG. 4A is a sectional view of the electronic device 20 as taken along line 4A-4A in FIG. 2A. In the embodiment, the tube formed by the side walls 232 and 232′ and the attaching wall 231 is a rectangular. However, this embodiment is not intended to limit the shape of the tube. In some embodiments, the heat sink can have different shape. Taking FIG. 4B as an example, which is a sectional view of an electronic device 20b according to another embodiment. Being different from the shape of the tube in FIG. 4A, the shape of the tube of a heat sink 23b formed by side walls 232a and 232b and the attaching wall 231 is trapezoid. The side wall 232a away from the attaching wall 231 is parallel to the attaching wall 231. The width W1 of the side wall 232a is smaller than the width W2 of the attaching wall 231.

FIG. 4C is a sectional view of an electronic device 20c according to another embodiment, disclosing another shape of the heat sink. In the embodiment, although the shape of the tube of a heat sink 23c formed by side walls 232c and 232d and the attaching wall 231 is also trapezoid and the side wall 232c away from the attaching wall 231 is parallel to the attaching wall 231, the width W3 of the side wall 232c is larger than the width W4 of the attaching wall 231.

FIG. 4D is a sectional view of an electronic device 20d according to another embodiment, disclosing a heat sink with a different shape. In the embodiment, the heat sink 23d includes one curved side wall 232e. Accordingly, the tube of the heat sink 23d formed by the side wall 232e and the attaching wall 231 is chord.

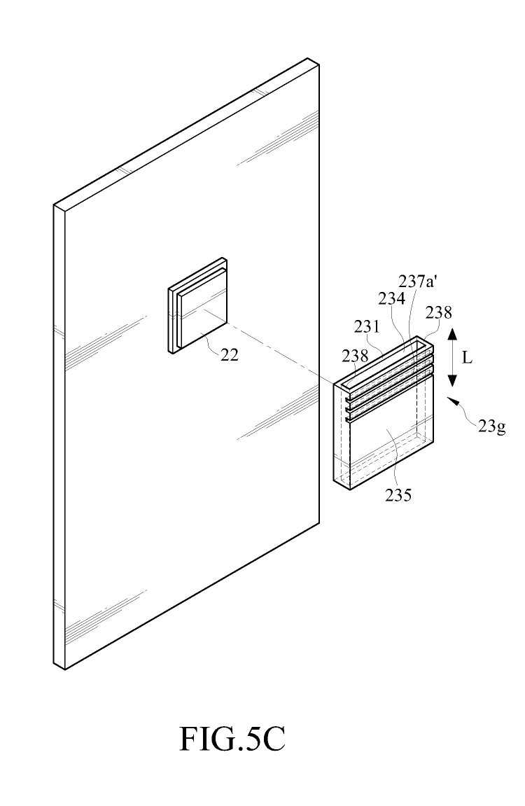

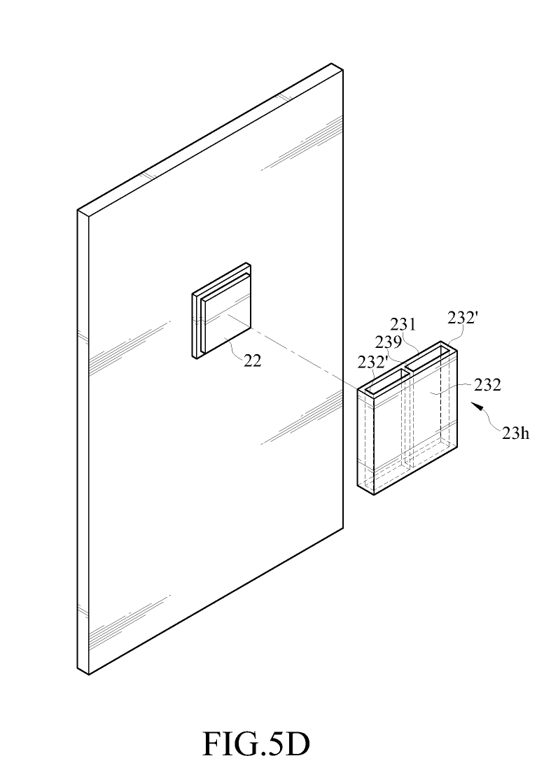

FIG. 5A is an exploded view a portion of an electronic device according to another embodiment. In the embodiment, a heat sink 23e includes three rectangular side walls 235 and 236. Each of the side walls 236 close to the attaching wall 231 has a through hole 236a, so that the cold air near the through hole 236a can also be attracted into the heat sink 23e for lowering the temperature the electronic element 22.

FIG. 5B is an exploded view of a portion of an electronic device according to another embodiment. In the embodiment, a heat sink 23f includes three rectangular side walls 237 and 238. The side wall 237 away from the attaching wall 231 has long through holes 237a The through holes 237a extends in a direction perpendicular to a direction L extending from the intake opening 233 to the outtake opening 234. The through holes 237a are parallel to each other and near the intake opening 233. Accordingly, the cold air near the through holes 237a can also be attracted into the heat sink 23f, so as to lower the temperature the electronic element 22.

FIG. 5C is an exploded view of a portion of an electronic device according to another embodiment. A heat sink 23g is similar to the heat sink 23f. However, through holes 237a′ of the heat sink 23g are near the outtake opening 234. Accordingly, a portion of the hot air in the heat sink 23g is removed from the through holes 237a′.

FIG. 5D is an exploded view of a portion of an electronic device according to another embodiment. In the embodiment, the heat sink 23g includes three rectangular side walls 232 and 232′. The heat sink 23h further includes a partition wall 239 between the attaching wall 231 and a portion of the side wall 232 away from the attaching wall 231. Accordingly, a portion of the heat of the electronic element 22 is conducted to the side wall 232 away from the attaching wall 231 through the partition wall 239, and then dissipated from the attaching wall 231.

There was an experiment comparing the efficiency of the conventional heat sinks 112a, 122a and the heat sinks 23, 23e, 23f, 23g, 23h of the present disclosure. In the experiment, the size of each of the heat sinks 112a, 122a, 23, 23e, 23f, 23g, 23h was 37.5 mm×37.5 mm×10.0 mm, and the size of the electronic element was 27.0 mm×27.0 mm. The circuit board 21, the electronic element 22, and the heat sinks 112a, 122a, 23, 23e, 23f, 23g, 23h was contained in a thin housing. The result of the experiment is shown in the Table 1 below.

TABLE 1

| | A | D | I | E | F | G | H |
|---|---|---|---|---|---|---|---|
| Heat Sink | N/A | 112a | 23 | 23e | 23f | 23g | 23h |
| Ta | 25 | 25 | 25 | 25 | 25 | 25 | 25 |
| Tc | 94.7 | 62.8 | 57.2 | 56.6 | 57.7 | 57.1 | 58.2 |
| Tj | 95.5 | 82.6 | 79.9 | 79.8 | 79.9 | 79.8 | 79.6 |
| Flow Rate | | 14405 | 30488 | | | | |
| (mm³/s) | | | | | | | |

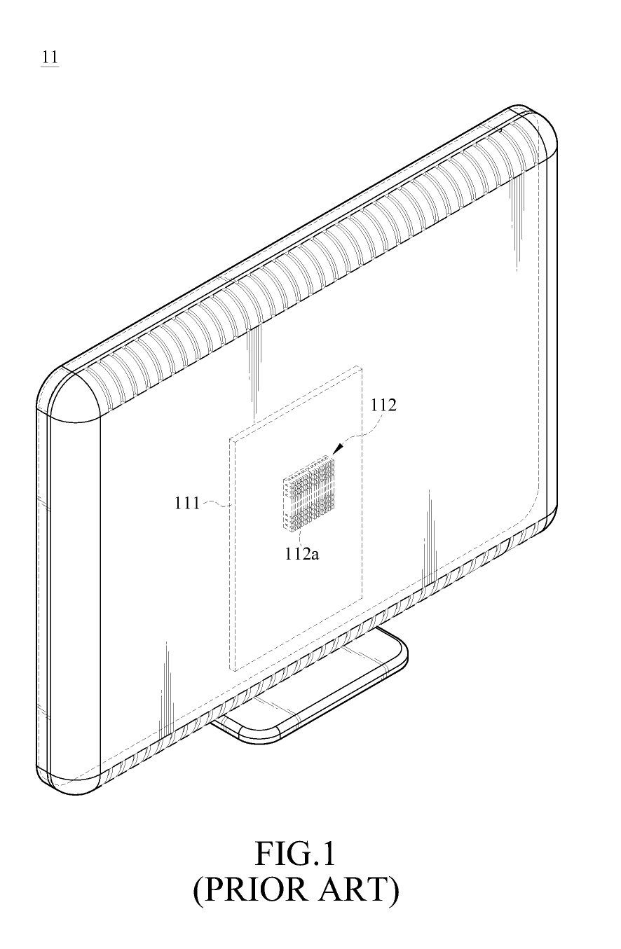

In Table 1, the column A shows the condition where no heat sink is used. The column D shows the condition where the heat sink 112a in FIG. 1 is used. The column I shows the condition where the heat sink 23 in FIG. 2B is used. The column E shows the condition where the heat sink 23e in FIG. 5A is used. The column F shows the condition where the heat sink 23f in FIG. 5B is used. The column G shows the condition where the heat sink 23g in FIG. 5C is used. The column H shows the condition where the heat sink 23h in FIG. 5D is used. Ta indicates the temperature of the environment. In the experiment, Ta is 25° C. Tc indicates the temperature of a portion of the heat sink far away from the electronic element 22, i.e. the outer-surface temperature of the heat sinks 112a, 122a, 23, 23e, 23f, 23g, and 23h. Tj is the temperature of the electronic element 22 calculated from the thermal conductivity of the heat sinks 112a, 122a, 23, 23e, 23f, 23g, 23h. The flow rate indicates the air quantity flowing through the intake opening per second, wherein the areas of the intake openings of the heat sinks 112a, 122a, 23, 23e, 23f, 23g, 23h are the same.

In Table 1, Tc of the heat sink 23, 23e, 23f, 23g, 23h is lower than 60° C., and Tc of the heat sink 112a, 122a is higher than 60° C. Tj of the heat sink 23, 23e, 23f, 23g, 23h is lower than 80° C., and Tj of the heat sink 112a, 122a is higher than 80° C. The flow rate of heat sink 23 is much more than the flow rate of conventional heat sink 112a, 122a. Therefore, the heat-dissipation efficiency of heat sink 23, 23e, 23f, 23g, 23h in the present disclosure is better than that of the conventional heat sink 112a, 122a. Among columns I, E, F, G, H, the lowest Tc presents in column E, and the lowest Tj presents in column H.

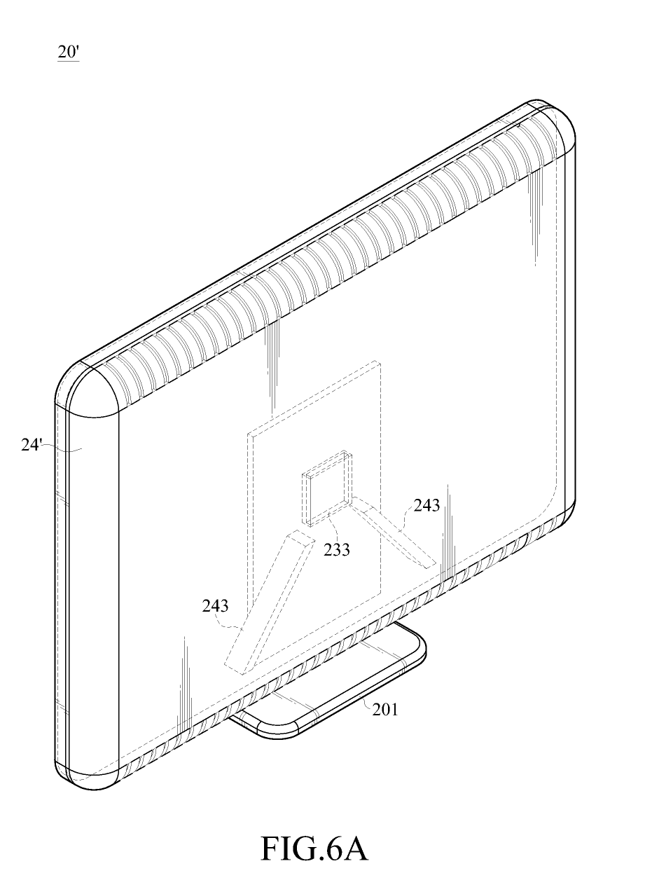

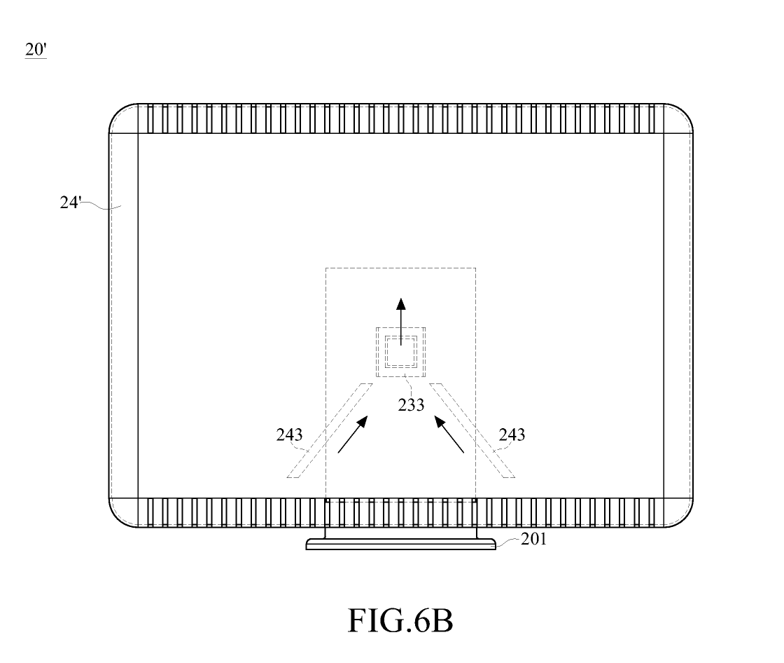

FIG. 6A is a perspective view of an electronic device 20′ according to another embodiment. FIG. 6B is a back view of the electronic device 20′ in FIG. 6A. In the embodiment, the housing 24′ further includes deflecting boards 243 mounted between the intake opening 233 and the base 201. The deflecting boards 243 are arranged as a taper. The narrow end of the taper is close to the intake opening 233, and the wide end of the taper is far away from the intake opening 233. Accordingly, the cold air can be guided by the deflecting boards, through the taper, and then into the intake opening 233.

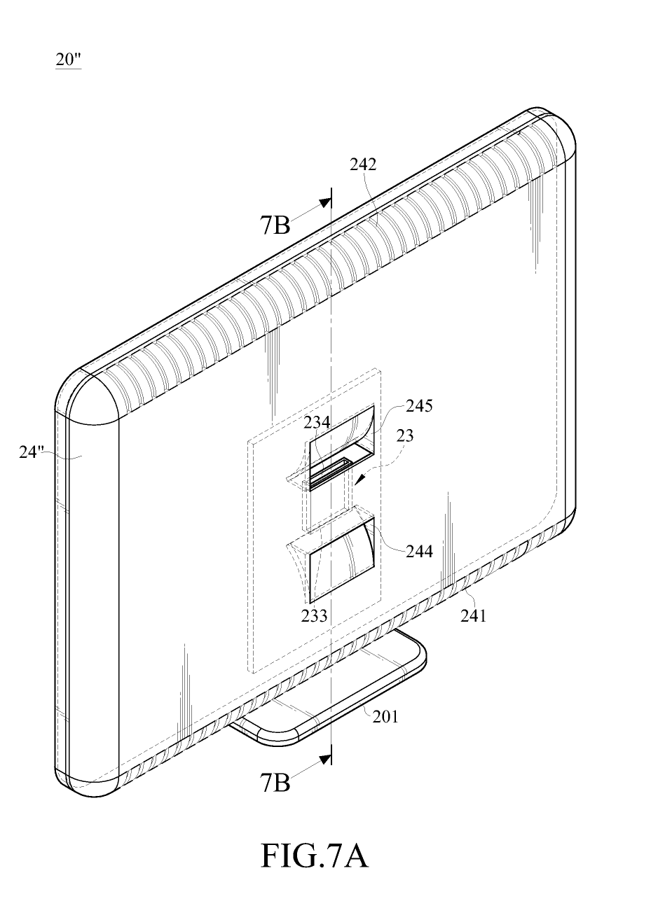

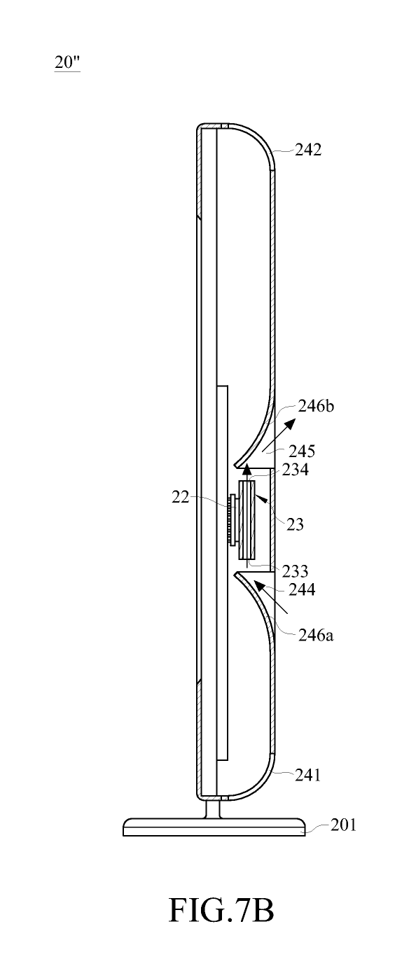

FIG. 7A is a perspective view of an electronic device 20″ according to another embodiment. FIG. 7B is a sectional view of the electronic device 20″ as taken along line 7B-7B in FIG. 7A. In the embodiment, the housing further has an intake hole 244 and an outtake hole 245. The intake hole 244 is close to the intake opening 233. The outtake hole 245 is close to the outtake opening 234. The intake hole 244 is closer to base 201 than the intake opening 233. The outtake hole 245 is farther away from the base 201 than the outtake opening 234. The housing 24′ further has surfaces 246a and 246b. One of the deflecting surfaces 246a is between the intake hole 244 and the intake opening 233, another deflector surface 246b is between the outtake hole 245 and the outtake opening 234. The deflecting surfaces 246a and 246b are configured to communicate the ambient outside the housing 24′ with the interior of the heat sink 23. When the size of the electronic device 20″ is so large that the intake hole 241 and outtake hole 242 are distant from the heat sink 23, the intake hole 244 and the outtake hole 245 help the heat sink 23 dissipate the heat generated by the electronic element 22.

According to the present disclosure, since the side walls extend from one end of the attaching wall to the opposite end of the attaching wall in sequence for forming a tube with the attaching wall, the heat sinks of the embodiments have higher heat-dissipation efficiency than those in the conventional electronic devices. In addition, since the shapes of the heat sinks of the embodiments are simple, the manufacturing cost of the heat sinks of the embodiments is low.

What is claimed is:

1. An electronic device having a base, comprising:
a circuit board;
an electronic element, mounted on the circuit board; and
a heat sink, attaching to the electronic element, comprising:
an attaching wall, attaching to the electronic element and having two opposite ends; and
at least one side wall, connecting to the ends of the attaching wall, the side wall and the attaching wall forming a tube with an intake opening and an outtake opening, the intake opening facing the base and the outtake opening opposite to the intake opening.

2. The electronic device according to claim 1, wherein the electronic element is a chip.

3. The electronic device according to claim 1, wherein the thickness of the heat sink is equal to or smaller than 10 mm.

4. The electronic device according to claim 1, wherein the attaching wall is rectangular.

5. The electronic device according to claim 4, wherein the heat sink comprises three rectangular side walls.

6. The electronic device according to claim 5, wherein the tube formed by the side walls and the attaching wall is a rectangular tube.

7. The electronic device according to claim 5, wherein the tube formed by the side walls and the attaching wall is a trapezoid tube.

8. The electronic device according to claim 7, wherein the side wall away from the attaching wall is parallel to the attaching wall.

9. The electronic device according to claim 5, wherein each of the side walls close to the attaching wall has a through hole, respectively.

10. The electronic device according to claim 1, wherein a portion of the side wall away from the attaching wall has a plurality of long through holes.

11. The electronic device according to claim 10, wherein the through holes extends perpendicularly to a direction extending from the intake opening to the outtake opening.

12. The electronic device according to claim 1, wherein the side wall is one curved side wall, the tube formed by the side wall and the attaching wall is a chord tube.

13. The electronic device according to claim 1, wherein the electronic device further comprises a housing covering the circuit board, the electronic element, and the heat sink, the housing has an intake hole and an outtake hole, the intake hole is close to the base, and the outtake hole is far away from the base.

14. The electronic device according to claim 1, wherein the electronic device further comprises a housing covering the circuit board, the electronic element, and the heat sink, the housing has an intake hole and an outtake hole, the intake hole is close to the intake opening, the outtake hole is close to the outtake opening, the intake hole is closer to base than the intake opening, and the outtake hole is farther away the base than the outtake opening.

15. The electronic device according to claim 14, wherein the housing further has a plurality of deflecting surfaces, one of the deflecting surfaces is between the intake hole and the intake opening, another deflector surface is between the outtake hole and the outtake opening, and the deflecting surfaces is configured to communicate outside of the housing and inside of the tube.

16. The electronic device according to claim 1, wherein the housing further has a plurality of deflecting boards mounted between the intake opening and the base, the deflecting boards are arranged as a taper, a narrow end of the taper is close to the intake opening, and a wide end of the taper is far away from the intake opening.

17. The electronic device according to claim 1, wherein the heat sink further comprises a partition wall between the attaching wall and a portion of the side wall away from the attaching wall.
